(19) United States
(12) Patent Application Publication
(10) Pub. No.: US 2007/0287231 A1
(43) Pub. Date: Dec. 13, 2007

(54) METHOD OF FORMING DECOUPLED COMB ELECTRODES BY SELF-ALIGNMENT ETCHING

(75) Inventors: Seok-whan CHUNG, Yongin-si (KR); Hyung CHOI, Yongin-si (KR); Seok-jin KANG, Yongin-si (KR); Young-chul KO, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/733,791

(22) Filed: Apr. 11, 2007

(30) Foreign Application Priority Data
Jun. 13, 2006 (KR) 10-2006-0053141

(51) Int. Cl. H01L 21/84

(52) U.S. Cl. 438/149

(57) ABSTRACT

A method of etching decoupled comb electrodes by self-alignment is provided The etching method is a self-alignment etching method for forming upper comb electrodes in a first silicon layer of a silicon on insulator (SOI) substrate and lower comb electrodes in a second silicon layer of the SOI substrate. The self-alignment etching method includes forming a first metal mask on the first silicon layer so as to cover portions of the first silicon layer where the upper comb electrodes are to be formed, forming a first photoresist (PR) mask on the first metal mask and portions of the first silicon layer corresponding to the lower comb electrodes, selectively etching the first silicon layer using the first PR mask as an etch barrier layer, selectively etching an insulating layer of the SOI substrate using the first PR mask as an etch barrier layer, selectively etching the second silicon layer of the SOI substrate using the first PR mask as an etch barrier layer, forming a second PR mask on portions of the second silicon layer corresponding to the upper comb electrodes, forming a second metal mask entirely on an exposed bottom surface of the second silicon layer including the second PR mask, removing the first and second PR masks, and etching the first and second silicon layers using the remaining first and second metal masks so as to form the upper comb electrodes and the lower comb electrodes.

### CROSS-REFERENCE TO RELATED PATENT APPLICATIONS

This application claims the benefit of Korean Patent Application No. 10-2006-0053141, filed on Jun. 13, 2006, in the Korean Intellectual Property Office, the disclosure of which is incorporated herein in its entirety by reference.

### BACKGROUND OF THE INVENTION

1. Field of the Invention

Methods consistent with the present invention relate to a method of forming comb electrodes of a micro-electro mechanical system (MEMS) device and, more particularly, to an etching method for forming decoupled comb electrodes by forming each comb electrode in a single layer using an upper silicon layer or a lower silicon layer of a silicon on insulator (SOI) substrate.

2. Description of the Related Art

In various technical fields related to display devices, laser printers, precise measuring instruments, precise machining devices, etc., much research is being carried out to develop a small-sized MEMS device that is manufactured using micro-machining technologies. For example, in a display device, a MEMS device is used as an optical scanner for reflecting or deflecting a scanning light beam onto a screen.

FIG. 1 is a perspective view of a related art MEMS device. Referring to FIG. 1, the MEMS device includes a rectangular frame 30, a stage 11 rotatably supported on the frame 30, and a plurality of fixed comb electrodes 20 and a plurality of driving comb electrodes 10 that extend from the frame 30 and the stage 11, respectively, toward each other. The driving comb electrodes 10 extend at regular intervals from both sides of the stage 11 toward the frame 30, and the fixed comb electrodes 20 extend from the frame 30 in parallel with each other and overlap with the driving comb electrodes 10. The driving comb electrodes 10 and the fixed electrodes 20 are arranged adjacent to each other so as to exert an electrostatic force on each other. The stage 11 is rotated about torsion bars 15 by the electrostatic force acting between the comb electrodes 10 and 20. For example, when the stage 11 is used as a micro mirror, the stage 11 reflects an incident laser beam onto a screen as the stage 11 rotates. The stage 11 is spaced a predetermined distance apart from a floor by a frame base 35, so that the stage 11 can rotate without interference with the floor.

FIG. 2 is a vertical cross-sectional view ken along the line II-II of FIG. 1. In FIG. 2, the frame base 35 is omitted for clarity. Referring to FIG. 2, the MEMS device is formed by etching a silicon on insulation (SOI) substrate using a predetermined pattern. The SOI substrate includes an insulating layer 45, and first and second silicon layer 41 and 42 that are bonded to opposite sides of the insulating layer 45. The comb electrodes 10 and 20 and the frame 30 are formed of the first and second silicon layers 41 and 42 in a multiple layer structure. Upper and lower portions 10U, 10L, 20U, and 20L of the comb electrodes 10 and 20 can be self-aligned in a vertical direction by deep etching the first and second silicon layers 41 and 42 using an etch mask.

For example, when the upper portions 10U and 20U of the driving comb electrodes 10 and the fixed comb electrodes 20 are grounded and a driving voltage (V) is supplied to the lower portions 20L of the fixed comb electrodes 20, the driving comb electrodes 10 are pulled down by an electrostatic force. Thus, the stage 11 where the driving comb electrodes 10 are formed is rotated in one direction. Then, in a reverse way, a driving voltage or a ground voltage is supplied to the upper and lower portions 10U, 10L, 20U, and 20L of the driving comb electrodes 10 and the fixed comb electrodes 20. E this case, the driving electrodes 10 are pulled upward by an electrostatic force, and thus the stage 11 is rotated in a reverse direction. That is, the driving voltage applied to the upper and lower portions 10U, 10L, 20U, and 20L should be periodically changed in order to rotationally vibrate the stage 11 (i.e., electrical switching is required). Furthermore, since different voltages are supplied to the upper and lower portions 10U, 10L, 20U, and 20L, the insulating layer 45 formed between the upper and lower portions 10U, 10L, 20U, and 20L should have a thickness of 2 μm or larger in order to prevent an electrical breakdown and a resulting short circuit. This makes etching of the SOI substrate difficult.

FIG. 3 is a vertical cross-sectional view of a related art MEMS device. Referring to FIG. 3, each driving comb electrode 50 and fixed comb electrode 60 is formed of a first silicon layer 81 or a second silicon layer 82 in a single layer format. The neighboring comb electrodes 50 and 60 are staggered. For example, when the driving comb electrodes 50 are grounded and a driving voltage (V) is supplied to the neighboring fixed comb electrodes 60, the driving comb electrodes 50 are attracted down by the fixed comb electrodes 60 and thus a stage where the driving comb electrodes 50 are formed is rotated. Next, when the driving voltage (V) is not supplied, the driving comb electrodes 50 return to an original position due to the torsion elasticity of an axle. In this decoupled structure of the comb electrodes 50 and 60, electrical switching is not required for driving the comb electrodes 50 and 60. Therefore, the circuit structure of the MEMS device is simple, and an insulating layer 85 of the MEMS device is not thick, making it easier to perform an etching process for the MEMS device.

In the related art, a double-sided aligning method is used to form the decoupled comb electrodes 50 and 60. In detail, one side of an SOI substrate is etched using a predetermined pattern to form driving electrodes 50, and then the other side of the SOI substrate is etched to form fixed electrodes 60 using the driving electrodes 50 as alignment marks. However, in the related art method, the aligning operation requires much time and manpower, thereby increasing process time and decreasing process yield. Furthermore, it is difficult to maintain a uniform gap between the comb electrodes 50 and 60 due to alignment errors. Therefore, when the comb electrodes 50 and 60 are overlapped with each other, mechanical interference can occur, and an undesired vibration mode, such as pull-in, yawing, or tilting mode, can arise. As a result, driving power is excessively consumed.

### SUMMARY OF THE INVENTION

Consistent with the present invention, a self-alignment etching method of forming decoupled comb electrodes is provided so as to precisely align upper comb electrodes and lower comb electrodes.

According to an aspect of the present invention, there is provided a method of forming upper comb electrodes in a first silicon layer of a silicon on insulator (SOT) substrate and lower comb electrodes in a second silicon layer of the SOI substrate, the method comprising: forming a first metal mask on the first silicon layer so as to cover portions of the first silicon layer where the upper comb electrodes are to be formed; forming a first photoresist (PR) mask on the first metal mask and portions of the first silicon layer corresponding to the lower comb electrodes; selectively etching the first silicon layer using the first PR mask as an etch barrier layer; forming a second PR mask on portions of the second silicon layer corresponding to the upper comb electrodes; selectively etching an insulating layer of the SOI substrate using the first PR mask as an etch barrier layer; selectively etching the second silicon layer of the SOI substrate using the first PR mask as an etch barrier layer; forming a second metal mask entirety on an exposed bottom surface of the second silicon layer including the second PR mask; removing the first and second PR masks; and etching the first and second silicon layers using the remaining first and second metal masks so as to form the upper comb electrodes and the lower comb electrodes.

The second PR mask may be aligned in a vertical direction with the upper electrodes which are formed by etching the first silicon layer. Regions of the second PR mask may be wider than the upper comb electrodes.

### BRIEF DESCRIPTION OF THE DRAWINGS

The above and other features and advantages of the present invention will become more apparent by describing in detail exemplary embodiments thereof with reference to the accompanying drawings, in which:

FIG. 1 is a perspective view of a related art MEMS device;

FIG. 2 is a vertical cross-sectional view taken along the line II-II of FIG. 1;

FIG. 3 is a vertical cross-sectional view of a related art MEMS device; and

FIGS. 4A through 4L are cross-sectional views for explaining an etching method according to an exemplary embodiment of the present invention.

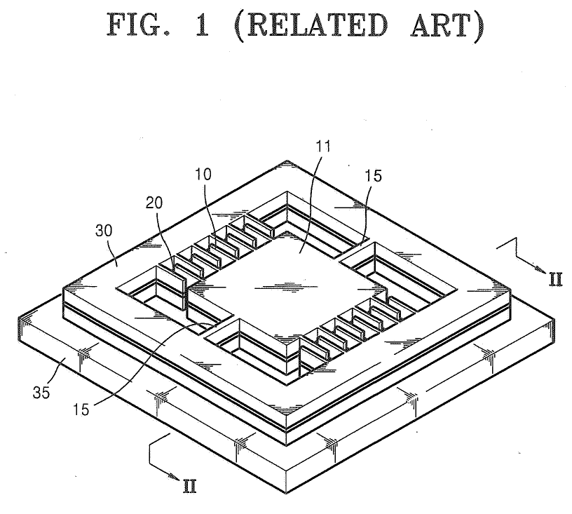

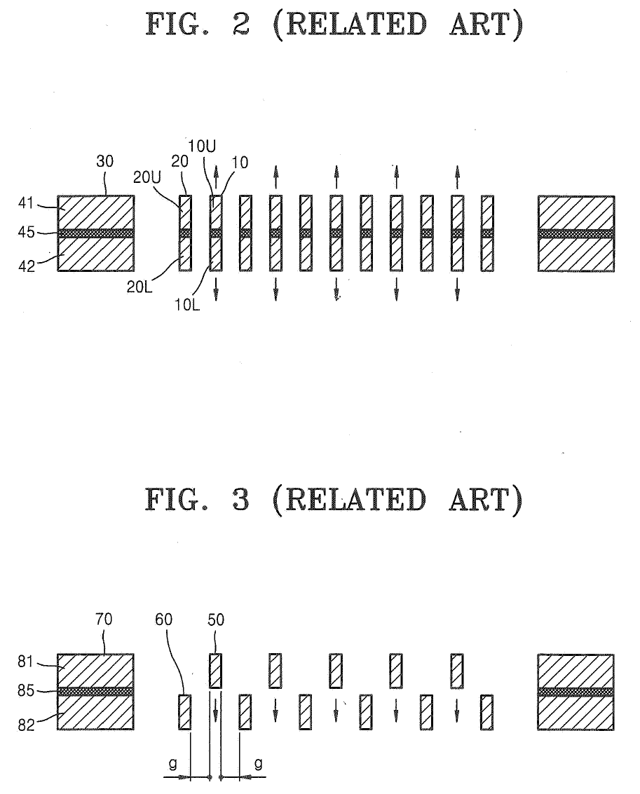

### DETAILED DESCRIPTION OF EXEMPLARY EMBODIMENTS OF THE INVENTION

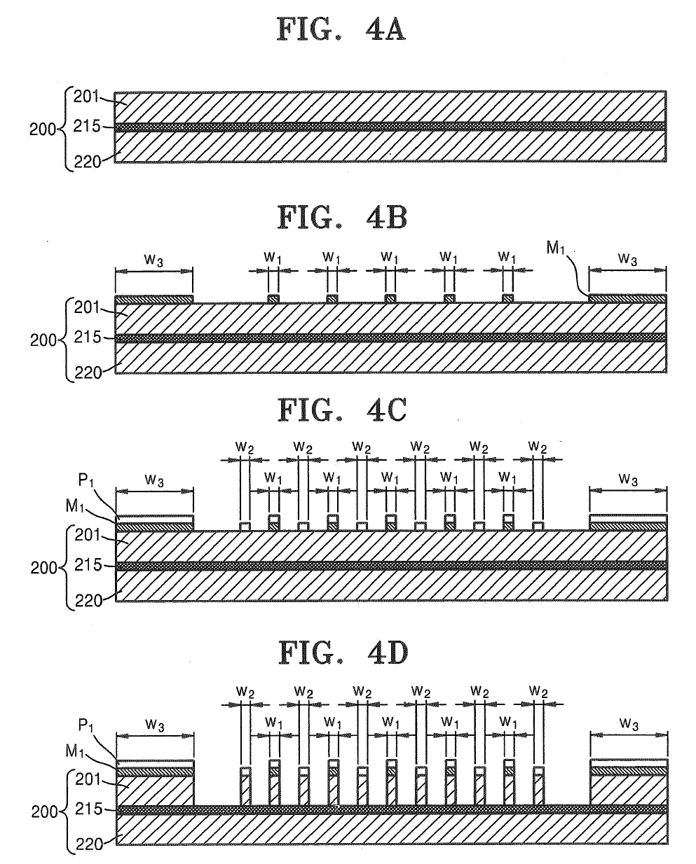

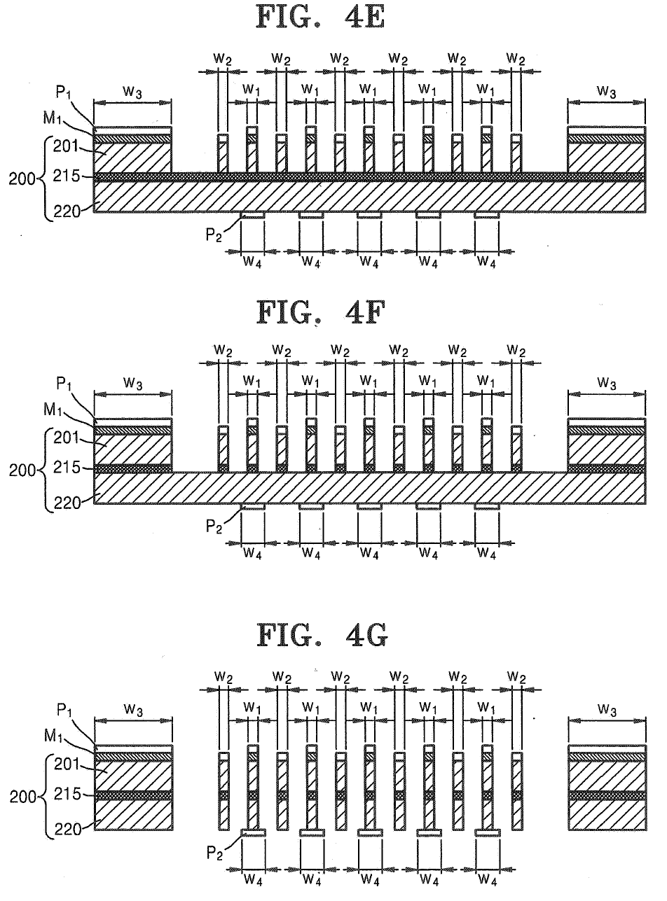

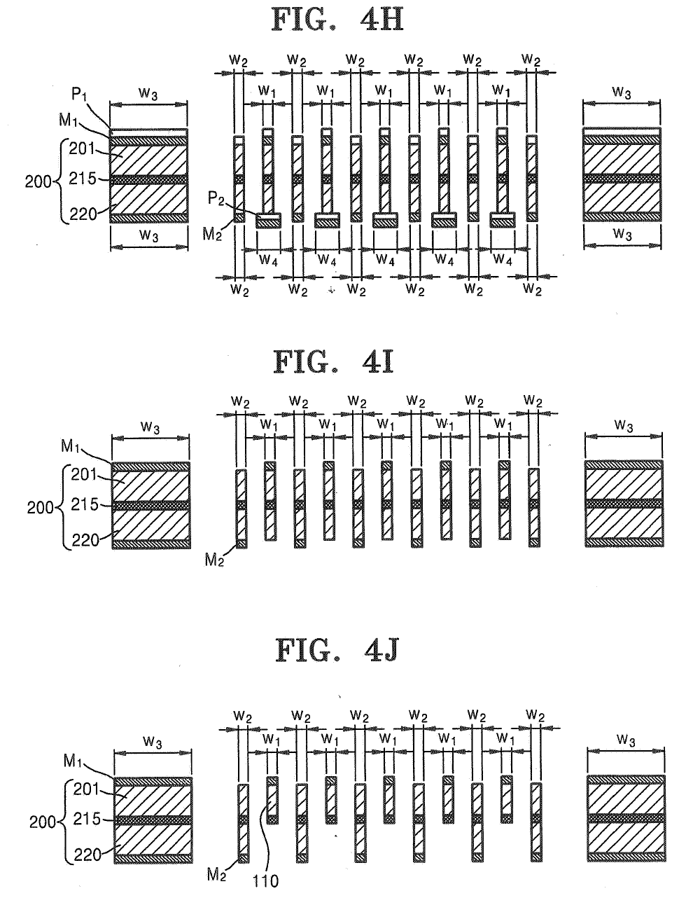

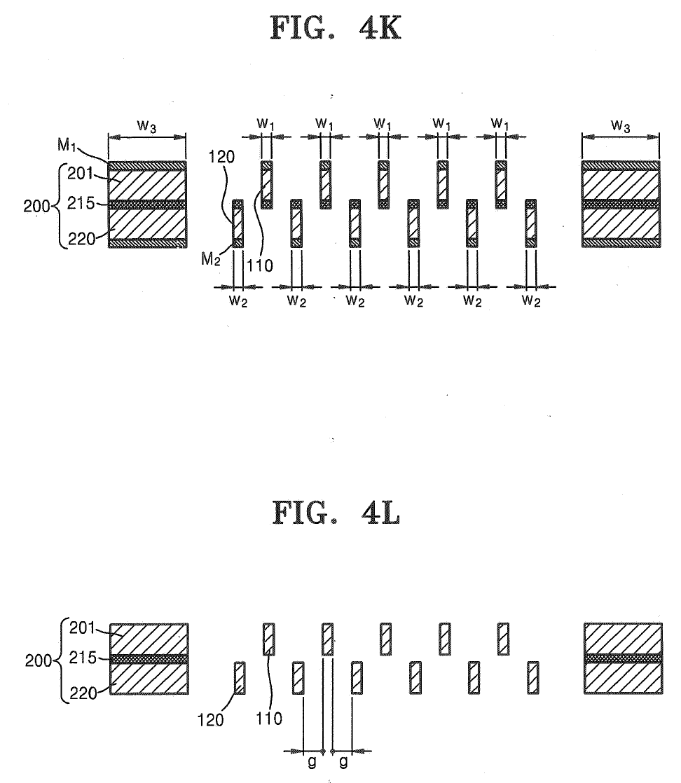

A self-alignment etching method will now be described more fully with reference to the accompanying drawings, in which exemplary embodiments of the invention are shown. FIGS. 4A through 4L are cross-sectional views for explaining a self-alignment etching method according to an exemplary embodiment of the present invention. Referring to FIG. 4A, a silicon on insulator (SOI) substrate 200 is prepared. The SOI substrate 200 includes an insulating layer 215 and first and second silicon layers 201 and 220 that are bonded to opposite sides of the insulating layer 215. The insulating layer 215 may be a silicon oxide layer formed by oxidizing a surface of a silicon layer. To prepare the SOI substrate 200, two silicon wafers can be surface treated and bonded together. Then, the two silicon wafers may be tightly bonded by heat treatment. That is, the SOI substrate 200 can be formed by silicon wafer direct bonding (SDB).

Referring to FIG. 4B, a first metal mask M1 is formed on the first silicon layer 201 in a predetermined region. The metal mask M1 has portions that cover an outer frame portion and inner driving comb portions of the SOI substrate 200 where an outer frame and inner driving combs will be formed. For example, the metal mask M1 can be formed of a thin aluminum film. The first metal mask M1 can be formed thinner than the first silicon layer 201. In detail, a thin aluminum layer is formed on an entire surface of the first silicon layer 201, and then the thin aluminum layer is patterned by a photolithography process that is well known to those of ordinary skill in the art.

Referring to FIG. 4C, a first photoresist (PR) mask P1 is formed in predetermined regions of the first metal mask M1 and the first silicon layer 201. The first PR mask P1 covers the outer frame portion W3 and the inner driving comb portions W1. Furthermore, the first PR mask P1 covers fixed comb portions W2 of the SOI substrate 200 where fixed combs are to be formed. For example, the first PR mask P1 can be formed as follows. A photoresist resin is formed on the first metal mask M1 and the first silicon layer 201, and then the photoresist resin is patterned by exposing and developing. Portions of the first silicon layer 201 exposed by the first PR mask P1 are later removed by etching (described later).

Referring to FIG. 4D, the portions of the first silicon layer 201 exposed by the first PR mask P1 are selectively removed. For example, the exposed portions of the first silicon layer 201 are removed by deep reaction ion etching (DRIE) until the insulating layer 215 is exposed. Through this etching process, the outer frame portion W3, the inner driving comb portions W1, and the fixed comb portions W2 are simultaneously formed.

Referring to FIG. 4E, a second PR mask P2 is formed on a bottom surface of the second silicon layer 220. The second PR mask P2 includes regions W4 aligned with the driving comb portions W1. The regions W4 are wide so as to sufficiently cover the driving comb portions W1. When alignment errors between the driving comb portions W1 and the second PR mask P2 are considered, the regions W4 of the second PR mask P2 may be wider than the driving comb portions W1 by predetermined alignment margins. The second PR mask P2 may be formed of a photoresist resin that can be easily dissolved by a selected organic solvent.

Referring to FIG. 4F, exposed portions of the insulating layer 215 are removed. For example, the exposed portions of the insulating layer 215 may be removed by a well known dry etching process until the second silicon layer 220 is exposed. Referring to FIG. 4G, exposed portions of the second silicon layer 220 are selectively removed by, for example, DRIE. In this way, the first and second silicon layer 201 and 220 are etched using the same PR mask P1. Therefore, a conventional double-sided aligning operation is not required, and thus alignment errors can be structurally reduced. Thus, uniform gaps can be maintained between comb electrodes.

Referring to FIG. 411, a second metal mask M2 is formed on the bottom surface of the patterned second silicon layer 220. The second metal mask M2 can be formed thinner than the second silicon layer 220. The second metal mask M2 is simultaneously formed on the exposed bottom surface of the second silicon layer 220 by sputtering or evaporation. In this way, the second metal mask M2 is formed on the bottom surfaces of the outer frame portion W3, the fixed comb portions W2, and the regions W4 of the second PR mask P2. Since the regions W4 of the second PR mask P2 covering the driving comb portions W1 are sufficiently wide, the second metal mask M2 does not directly contact the driving comb portions W1.

Referring to FIG. 4I, the first and second PR masks P1 and P2 are simultaneously removed. The first and second PR masks P1 and P2 are removed by a stripping process using an organic solvent selected depending on the materials of the first and second PR masks P1 and P2. When the second PR mask P2 is removed, portions of the second metal mask M2 attached to the second PR mask P2 are removed together. Thus, lower ends of the driving comb portions W1 are exposed.

Referring to FIG. 4J, the exposed lower ends of the driving comb portions W1 are removed using the second metal mask M2 as an etch barrier layer. For example, the exposed lower ends of the driving comb portions W1 may be removed by DRIE until the insulating layer 215 is exposed. In this way, the formation of driving comb electrodes 110 is completed. Referring to FIG. 4K, exposed upper ends of the fixed comb portions W2 are removed using the first metal mask M1 as an etch barrier layer. For example, the exposed upper ends of the fixed comb portions W2 may be removed by DRIE until the insulating layer 215 is exposed. In this way, the formation of fixed comb electrodes 120 is completed.

Referring to FIG. 4L, the first and second metal masks M1 and M2 are removed. For example, the first and second metal masks M1 and M2 are simultaneously removed using an aluminum etchant. Although the first and second metal masks M1 and M2 are not necessarily removed, the first and second metal masks M1 and M2 may be removed in order to eliminate the possibility of obstructing the formation of a wiring pattern including electrode pads. The insulating layer 215 formed on the comb electrodes 110 and 120 can be removed or not removed depending on application conditions. In the current exemplary embodiment, a self-alignment etching method is used to form the decoupled comb electrodes 110 and 120 by etching using the same mask. Therefore, the comb electrodes 110 and 120 can be precisely aligned with each other, and uniform horizontal gaps can be formed between the comb electrodes 110 and 120.

Consistent with the present invention, the comb electrodes are formed of an upper single silicon layer or a lower single silicon layer in order to form an upper and lower comb electrode structure. For this, self-alignment etching is employed to form the decoupled comb electrodes by using the same etch mask. Therefore, when compared with the conventional double-sided aligning method, less time and manpower are required to align the comb electrodes, and thus manufacturing costs can be reduced and process yield can be increased. Furthermore, alignment errors can be structurally removed or reduced, and thus the comb electrodes can be precisely aligned. Therefore, the process margin is practically increased due to the removal or decrease of the alignment errors, thereby increasing the process yield. Moreover, undesired vibration modes caused by alignment errors, such as pull-in, yawing, and tilting modes, can be reduced, and thus dynamic characteristics and the driving force of the comb electrodes are improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming upper comb electrodes in a first silicon layer of a silicon on insulator (SOI) substrate and lower comb electrodes in a second silicon layer of the SOI substrates the method comprising:
forming a first metal mask on the first silicon layer so as to cover portions of the first silicon layer where the upper comb electrodes are to be formed;
forming a first photoresist (PR) mask on the first metal mask and portions of the first silicon layer corresponding to the lower comb electrodes;
selectively etching the first silicon layer using the first PR mask as an etch barrier layer;
forming a second PR mask on portions of the second silicon layer corresponding to the upper comb electrodes;
selectively etching an insulating layer of the SOI substrate using the first PR mask as an etch barrier layer;
selectively etching the second silicon layer of the SOI substrate using the first PR mask as an etch barrier layer;
forming a second metal mask entirely on an exposed bottom surface of the second silicon layer including the second PR mask;
removing the first and second PR masks; and
etching the first and second silicon layers using the remaining first and second metal masks so as to form the upper comb electrodes and the lower comb electrodes.

2. The method of claim 1, wherein the second PR mask is aligned in a vertical direction with the upper comb electrodes which are formed by etching the first silicon layer.

3. The method of claim 1, wherein regions of the second PR mask are wider than the upper comb electrodes.

4. The method of claim 1, wherein the first and second PR masks are formed of a photoresist resin soluble in a predetermined organic solvent.

5. The method of claim 1, wherein each of the first and second metal masks is formed of an aluminum film formed using an etch pattern.

6. The method of claim 1, wherein the second metal mask is formed by one of sputtering and evaporation.

7. The method of claim 1, wherein the removing of the first and second PR masks comprises applying an organic solvent, for dissolving only the first and second PR masks, to the entire SOI substrate so as to remove the first and second PR masks simultaneously.

8. The method of claim 1, wherein when the second PR mask is removed, portions of the second metal mask attached to the second PR mask are removed together with the second PR mask.

9. The method of claim 1, farther comprising removing the first and second metal mask after the forming of the upper and lower comb electrodes.

10. The method of claim 1 further comprising removing the insulating layer attached to lie upper and lower comb electrodes after the forming of the upper and lower comb electrodes.
